(19) United States
(12) Patent Application Publication
(10) Pub. No.: US 2019/0218659 A1
(43) Pub. Date: Jul. 18, 2019

(54) MULTILAYER FILM FORMATION METHOD

(71) Applicant: NITTO DENKO CORPORATION, Ibaraki-shi, Osaka (JP)

(72) Inventors: Shunsuke SHUTO, Ibaraki-shi (JP); Satoru SAKI, Ibaraki-shi (JP)

(73) Assignee: NITTO DENKO CORPORATION, Ibaraki-shi, Osaka (JP)

(21) Appl. No.: 16/306,622

(22) PCT Filed: Jun. 2, 2017
(86) PCT No.: PCT/JP2017/020587

§ 371 Date: Dec. 3, 2018

(30) Foreign Application Priority Data
Jun. 7, 2016 (JP) 2016-113713

(51) Int. Cl. C23C 14/54; C23C 14/34

(52) U.S. Cl. CPC C23C 14/542; C23C 14/34

(57) ABSTRACT

To realize film thickness correction of each layer without waste of material and time in the film formation method for a multilayer film in which each layer constituting the multilayer film is laminated one by one with a time interval. The film formation method for a multilayer film includes the steps of setting a target value (target thickness value) of a thickness of each layer, obtaining an estimated thickness (estimated thickness value) of each layer of a formed multilayer film 6, obtaining a film formation parameter change amount of each layer for minimizing a difference between the target thickness value and the estimated thickness value of each layer, and sequentially changing film formation parameters of each layer by the film formation parameter change amount of each layer with a time interval.

### BACKGROUND OF THE INVENTION

### Field of the Invention

The present invention relates to a film formation method for a multilayer film.

### Description of the Related Art

The multilayer film is a film in which a plurality of films are laminated. Each film constituting the multilayer film is referred to as each layer. The multilayer film is manufactured by successively forming each layer on a substrate. When forming a multilayer film, it is not always possible to form each layer with a target thickness at all times. Therefore, film formation is performed while correcting the film formation parameters of each layer and adjusting the thickness of each layer. For example, a method for correcting the film formation parameters of each layer by utilizing optical characteristics of the multilayer film having completed film formation is disclosed in Patent Document 1 (Japanese Unexamined Patent Application Publication No. 2006-71402).

In Patent Document 1, four layers of a first TiO₂ film, a first SiO₂ film, a second TiO₂ film, and a second SiO₂ film are sequentially formed on a long film. Then, the thicknesses of the first TiO₂ film, the first SiO₂ film, the second TiO₂ film, and the second SiO₂ film are estimated based on the hue of the reflected light of the multilayer film, having completed film formation, and the adjusted value of the thickness of each layer is obtained. Next, the film formation parameters are adjusted in accordance with the adjusted value of the thickness of each layer.

### PRIOR ART DOCUMENT

### Patent Document

Patent Document 1: Japanese Unexamined Patent Application Publication No. 2006-71402

### SUMMARY OF THE INVENTION

An object of the present invention is to realize film thickness correction of each layer without waste of material and time in a film formation method for a multilayer film in which each layer constituting the multilayer film is laminated one by one with a time interval.

The summary of the present invention is described as below.

In a first preferred aspect of the present invention, there is provided a multilayer film formation method in which each layer constituting the multilayer film is laminated one by one with a time interval. The film formation method for a multilayer film of the present invention includes the following steps:

a step of setting a target value (target thickness value) of the thickness of each layer;

a step of obtaining an estimated thickness (estimated thickness value) of each layer of the formed multilayer film;

a step of obtaining a film formation parameter change amount of each layer for minimizing the difference between the target thickness value and the estimated thickness value of each layer;

a step of sequentially changing film formation parameters of each layer used for actual film formation by a film formation parameter change amount of each layer with a time interval;

In a second preferred aspect of the multilayer film formation method according to the present invention, a spectral reflectance of the multilayer film is used to find the estimated thickness value of the multilayer film.

In a third preferred aspect of the multilayer film formation method according to the present invention, a hue of reflected light of the multilayer film is used to find the estimated thickness value of the multilayer film.

In a fourth preferred aspect of the multilayer film formation method according to the present invention, each layer constituting the multilayer film is formed by a sputtering apparatus.

In a fifth preferred aspect of the multilayer film formation method according to the present invention, the film formation parameters are one or more of a flow rate of a sputtering gas, a flow rate of a reactive gas, and a sputtering power.

In a sixth preferred aspect of the multilayer film formation method according to the present invention, one or more of the flow rate of the sputtering gas, the flow rate of the reactive gas, and the sputtering power are feedback-controlled by a plasma emission monitoring (PEM) control system or an impedance control system.

In a seventh preferred aspect of the multilayer film formation method according to the present invention, the multilayer film is formed on the surface of a long substrate film.

In an eighth preferred aspect of the multilayer film formation method according to the present invention, actually measured optical values are measured at predetermined intervals in the longitudinal direction of the long substrate film on which the multilayer film is formed.

In a ninth preferred aspect of the multilayer film formation method according to the present invention, the multilayer film is an optical multilayer film.

According to the present invention, in the film formation method for a multilayer film in which each layer constituting the multilayer film is laminated one by one with a time interval, adjustment of film thickness of each layer is realized without wasting neither material nor time. For example, when forming a multilayer film on a long film, a multilayer film in which film formation parameters of all layers are adjusted from one position in the longitudinal direction of the long film is obtained. Therefore, for example, in the case of changing the film formation parameters of the first layer and the second layer, a formation of such an unusable multilayer film as to have only the film formation parameters of the first layer being adjusted while the film formation parameters of the second layer remain unchanged is prevented. Therefore, waste of neither the substrate, the film forming material, nor time occurs.

### BRIEF DESCRIPTION OF THE DRAWINGS

FIG. 1(a) to 1(f) are schematic diagrams of a multilayer film according to the present invention.

FIG. 2 is a schematic diagram of a sputtering apparatus for a multilayer film according to the present invention.

### DESCRIPTION OF THE PREFERRED EMBODIMENTS

[Multilayer Film]

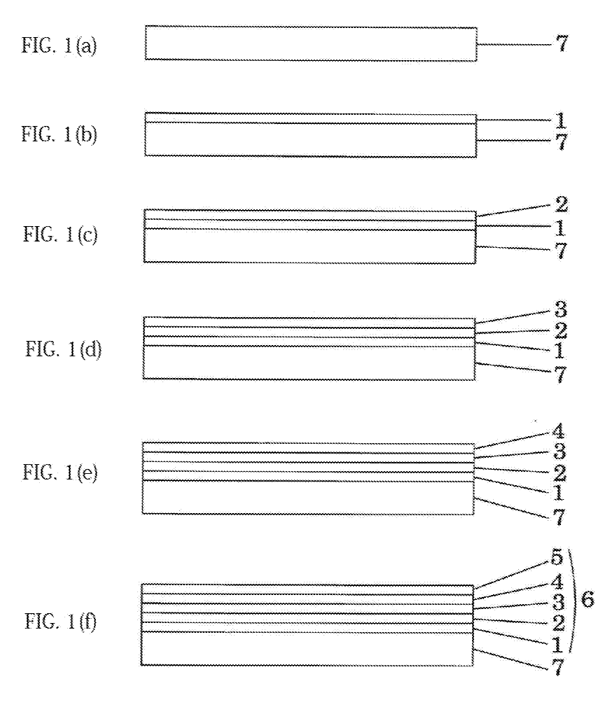

FIG. 1(a) to 1(f) schematically show an example of a multilayer film according to the present invention. The number of layers of a multilayer film 6 is not limited. FIG. 1(a) to 1(f) show a case of five layers. FIG. 1(a) is a substrate 7 for laminating the multilayer film 6. Examples of the material of the substrate 7 include a glass plate, a glass film, a plastic plate, a plastic film, a metal coil, a metal plate and the like. The material, thickness, shape (plane, curved surface, sheet or long film, etc.), and the like of the substrate 7 are not limited.

FIG. 1(b) shows a state in which a first layer 1 is formed on the substrate 7. Examples of the first layer 1 include a transparent conductive film, a photocatalytic film, a gas barrier film, a light interference film, and the like, but the type of the film is not limited. Examples of the film formation method of the first layer 1 include a sputtering method, a vapor deposition method, a CVD method, and the like, but the film formation method is not limited.

FIG. 1(c) shows a state in which a second layer 2 is formed on the first layer 1. FIG. 1(d) shows a state in which a third layer 3 is formed on the second layer 2. FIG. 1(e) shows a state in which a fourth layer 4 is formed on the third layer 3. FIG. 1(f) shows a state in which a fifth layer 5 is formed on the fourth layer 4. The types of films and film formation methods of the second layer 2 to the fifth layer 5 are the same as those of the first layer 1.

Materials, functions, thicknesses, film formation methods, and the like of the first layer 1 to the fifth layer 5 are appropriately designed according to the use of the multilayer film 6 and the like. In case of the optical use of the multilayer film, the multilayer film is called an optical multilayer film. Optical multilayer films are widely used for antireflection coatings and the like. A sputtering method, considering the variety of film materials that can be used, high hardness quality of film that can be obtained, and high accuracy of film thickness that can be obtained at large area, is often used as a film formation method for a multilayer film.

When forming a multilayer film, it is difficult to match the thickness of each layer with the target thickness value completely. For example, in the case of the sputtering method, the thickness of each layer is influenced by the partial pressure of sputtering gas, for example. However, even if the setting of the sputtering gas flowmeter is kept constant, the actual partial pressure of the sputtering gas fluctuates depending on temperature and pressure. The thickness of each layer adjustments in accordance with the fluctuation of the partial pressure of the sputtering gas. Such fluctuations inevitably occur not only in the partial pressure of the sputtering gas but also in many film formation parameters, such as the flow rate and partial pressure of the reactive gas, the cathode voltage, the target remaining amount, the distance between a film forming roll and the target, the temperature of the film forming roll, and the transfer speed of a substrate film. Therefore, it is inevitable that the thickness of each layer changes over time even if the film formation parameters are kept constant.

[Estimation of Multilayer Film Thickness]

The thickness of each layer of the multilayer film can be known accurately by observing the cross section of the multilayer film with an electron microscope. However, particularly in the case of forming a multilayer film on a long film, it is not practical to cut out samples frequently from the long film and observe the cross section. Therefore, the thickness of each layer of the multilayer film is estimated by a non-destructive method.

In the present invention, as an example of a non-destructive method, the formed multilayer film is irradiated with light, and the thickness of each layer is estimated using the optical value of the reflected light or the transmitted light. The optical value used for estimating the thickness of each layer is, for example, spectral reflectance, hue of reflected light, spectral transmittance, or hue of transmitted light.

Since it is inevitable that the thickness of each layer changes over time when a multilayer film is formed on a long substrate film, actually measured optical values are measured at predetermined intervals in the longitudinal direction of the long substrate film on which the multilayer film is formed.

[Film Thickness Estimation of Each Layer]

An example of the film thickness estimation method used in the present invention will now be described. In this film thickness estimation method, first, an estimated thickness value of each layer is assumed, and a theoretical optical value corresponding to the estimated thickness value is obtained by theoretical calculation. In the first theoretical calculation, the estimated thickness value of each layer is set as the target thickness value (designed thickness value). Next, the theoretical optical value and the actually measured optical value are compared. The step of comparing the theoretical optical value with the actually measured optical value is repeated n times (n=1, 2, 3, 4, . . . ) by varying the estimated thickness value of each layer until the optical value difference (the difference between the actually measured optical value and the theoretical optical value) satisfies a preset convergence condition (for example, a standard value of the difference between the actual measurement value of the spectral reflectance and the theoretical value). The estimated thickness value of each layer when the optical value difference satisfies the preset convergence condition is set as the most reliable estimated thickness value (“most probable estimated thickness value”) of each layer. In the following description, as an example, a case where the optical value difference satisfies the convergence condition after the step of comparing the theoretical optical value with the actually measured optical value is repeated three times (n=3) will be described.

(1) Depending on the purpose of the multilayer film, the target thickness value of each layer is set based on the theoretical calculation. For example, if the multilayer film is a transparent conductive film, a theoretical calculation is performed based on standard values of the light transmittance and the electric resistance value to set the target thickness value of each layer. If the multilayer film is an antireflection optical interference film, for example, the target thickness value of each layer is set to minimize the intensity of reflected light. The target thickness value of each layer is also called the designed thickness value of each layer.

(2) By theoretical calculations, theoretical optical values (for example, spectral reflectance or hue of reflected light) of the multilayer film when the thickness of each layer is the target thickness value are obtained. According to the present invention, in a case where the thickness of each layer is the target thickness value, theoretical optical value is referred to as a “first theoretical optical value”. In theoretical calculation, reflectance and transmittance of the substrate are taken into consideration as necessary.

(3) The actually formed multilayer film is irradiated with light and the optical value (for example, spectral reflectance or hue of reflected light) of the reflected light or the optical value (for example, spectral transmittance or hue of transmitted light) of the transmitted light is measured. In the present invention, an optical value obtained by measuring the actually formed multilayer film is referred to as an “actually measured optical value”.

(4) Although the thickness of each layer of the actually formed multilayer film is unknown, in order to proceed with the film thickness estimation process, it is necessary to assume some kind of film thickness. Therefore, in the present invention, the initial estimated value of the thickness of each layer is set as the target thickness value (designed thickness value). In the present invention, the estimated value of the thickness of each layer for the first calculation is referred to as a “first estimated thickness value”. Accordingly, the “first estimated thickness value” of each layer is the target thickness value. Since the first estimated thickness value of each layer is the same as the target thickness value, the theoretical optical value corresponding to this is the “first theoretical optical value”.

(5) In the present invention, the difference between the actually measured optical value and the first theoretical optical value is referred to as a “first optical value difference”. The first optical value difference is, in a case where the optical value is a spectral reflectance, the difference between the actual measurement value of the spectral reflectance and the theoretical value at the first time, whereas in a case where the optical value is the hue of the reflected light, the first optical value difference is the difference between the actual measurement value of the hue of the reflected light and the theoretical value at the first time.

(6) If the first optical value difference satisfies a preset convergence condition, the first estimated thickness value is set as the most reliable estimated thickness value of each layer, and the film thickness estimation process is terminated. In the present invention, the most reliable estimated thickness value of each layer is referred to as the “most probable estimated thickness value”. Therefore, in this case, the first estimated thickness value becomes the most probable estimated thickness value. In a case where the first optical value difference does not satisfy the preset convergence condition, the film thickness estimation process is continued. In a case where the optical value is the spectral reflectance, the preset convergence condition is that the difference between the actual measurement value of the spectral reflectance and the theoretical value at the first time is equal to or smaller than a preset standard value. In a case where the optical value is the hue of the reflected light, the preset convergence condition is that the difference between the actual measurement value of the hue of the reflected light and the theoretical value at the first time is equal to or smaller than a preset standard value.

(7) In a case where the first optical value difference does not satisfy the preset convergence condition, a second estimated thickness value of the thickness of each layer, which is expected to obtain an optical value difference smaller than the first optical value difference, is set. In the present invention, the estimated value of the thickness of each layer for the second calculation is referred to as the “second estimated thickness value”. The second estimated thickness value can be obtained by using, for example, a curve fitting method, based on the comparison result between the theoretical value at the first time and the actual measurement value.

(8) In a case where the thickness of each layer is the second estimated thickness value, a theoretical optical value (for example, spectral reflectance or hue of reflected light) is obtained by theoretical calculation. In the present invention, this theoretical optical value is referred to as a “second theoretical optical value”.

(9) The difference between the actually measured optical value and the second theoretical optical value is obtained. In the present invention, the difference between the actually measured optical value and the second theoretical optical value is referred to as a “second optical value difference”. The second optical value difference is the difference between the actual measurement value of the spectral reflectance and the theoretical value at the second time in a case where the optical value is the spectral reflectance, and is the difference between the actual measurement value of the hue of the reflected light and the theoretical value at the second time in a case where the optical value is the hue of the reflected light.

(10) If the second optical value difference satisfies a preset convergence condition, the second estimated thickness value is set as the most probable estimated thickness value of each layer, and the film thickness estimation process is terminated. If the second optical value difference does not satisfy the preset convergence condition, the film thickness estimation process is continued. The preset convergence condition is the same as in the case of the first optical value difference.

(11) In a case where the second optical value difference does not satisfy the preset convergence condition, a third estimated thickness value of the thickness of each layer, which is expected to obtain an optical value difference smaller than that of the second optical value difference, is set. In the present invention, the estimated value of the thickness of each layer at the third time is referred to as the “third estimated thickness value”. The third estimated thickness value can be obtained by using, for example, a curve fitting method, based on the comparison result between the theoretical value at the second time and the actual measurement value.

(12) In a case where the thickness of each layer is the third estimated thickness value, a theoretical optical value (for example, spectral reflectance or hue of reflected light) is obtained by theoretical calculation. In the present invention, this theoretical optical value is referred to as a “third theoretical optical value”.

(13) The difference between the actually measured optical value and the third theoretical optical value is obtained. In the present invention, the difference between the actually measured optical value and the third theoretical optical value is referred to as a “third optical value difference”. The third optical value difference is the difference between the actual measurement value of the spectral reflectance and the theoretical value at the third time in a case where the optical value is spectral reflectance, and is the difference between the actual measurement value of the hue of the reflected light and the theoretical value at the third time in a case where the optical value is the hue of the reflected light.

(14) In a case where the third optical value difference satisfies a preset convergence condition, the third estimated thickness value is set as the most probable estimated thickness value of each layer, and the estimation process of film thickness ends. The preset convergence condition is the same as in the case of the first optical value difference. In a case where the third optical value difference does not satisfy the preset convergence condition, the estimation process of film thickness continues. Here, it is assumed that the third optical value difference satisfies a preset convergence condition. Therefore, the third estimated thickness value is set as the most probable estimated thickness value of each layer, and the estimation process of film thickness ends.

Actually, the above steps are repeated until the difference between the actually measured optical value at the n-th time (n=1, 2, 3, 4, 5, . . . ) and the n-th theoretical optical value (this is referred to as an “n-th optical value difference”) satisfies the preset convergence condition, and finally the most probable estimated thickness value of each layer is obtained. The preset convergence condition is the same as in the case of the first optical value difference.

After the completion of the film thickness estimation, the film formation parameters are adjusted to minimize the difference between the most probable estimated thickness value of each layer and the target thickness value of each layer, and the thickness of each layer is optimized.

When estimating the thickness of each layer, it is also possible to include the step of calculating the optimum thickness of each layer with reference to the spectral reflectance or the hue of the reflected light and determining, based on the calculation, the layer whose thickness is to be adjusted among all the layers. As a result, it is possible to minimize the number of layers of which the film formation parameters are to be adjusted.

[Film Thickness Correction of Each Layer]

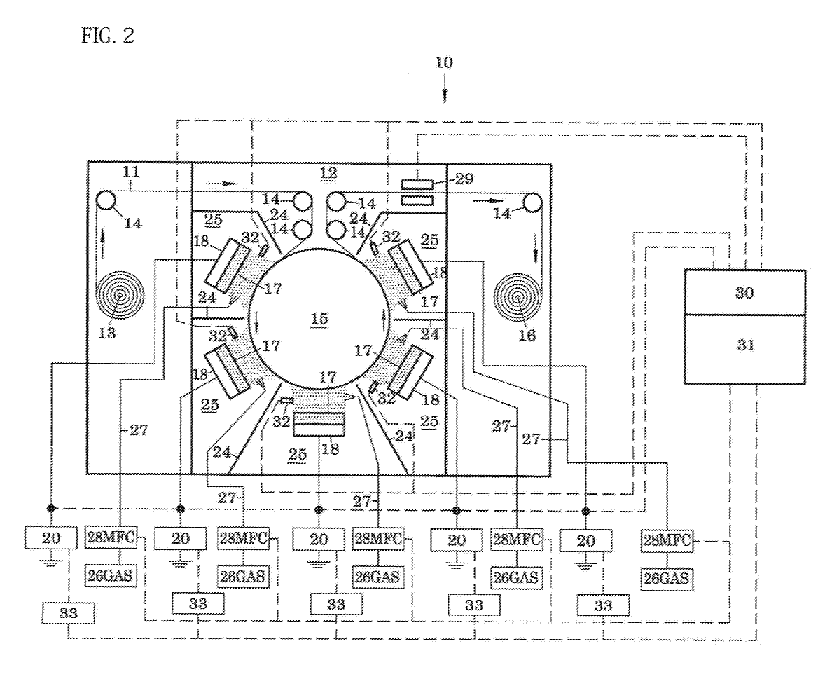

A method of correcting the thickness of each layer of the multilayer film will be explained by giving an example in which a multilayer film is formed on a long film by using a sputtering apparatus. FIG. 2 shows a schematic diagram of a sputtering apparatus for a multilayer film according to the present invention. A sputtering apparatus 10 is a device for forming a multilayer film on a long film 11. In FIG. 2, a thin solid line indicates an electric wiring or a gas pipe, and a broken line indicates a signal line, such as a spectral reflectance, a plasma emission intensity, a cathode voltage, and a gas flow rate. Note that FIG. 2 shows a drawing of a multilayer film being formed on the long film 11.

The sputtering apparatus 10 includes, in a vacuum chamber 12, a supply roll 13 for the long film 11, a guide roll 14 for guiding the transferring of the long film 11, a cylindrical film forming roll 15 for winding the long film 11 slightly shorter than one turn, and a storage roll 16 for storing the long film 11. The film forming roll 15 rotates about its own central axis. During film formation, the film forming roll 15 rotates, and the long film 11 is transferred in synchronization with the rotation of the film forming roll 15.

Targets 17 are placed around the film forming roll 15 so as to face the film forming roll 15. The targets 17 are disposed at a predetermined distance from the film forming roll 15. The central axis of the film forming roll 15 and the targets 17 are parallel. In FIG. 2, there are five targets 17, but the number of targets 17 is not limited. On the outside of the target 17 (the opposite side to the film forming roll 15), a cathode 18 is placed in intimate contact with the target 17. The target 17 and the cathode 18 are mechanically and electrically coupled.

Each cathode 18 is connected to a sputtering power supply 20. Since the cathode 18 and the target 17 have the same electric potential, the sputtering power supply 20 is connected to the target 17. A matching box (not shown) is not necessary in a case where the sputtering power supply 20 is direct current (DC, pulse DC) or alternating current (MF-AC) in the MF (Middle Frequency) region, but is inserted between the cathode 18 and the sputtering power supply 20 in a case of alternating current (RF-AC) in the RF (Radio Frequency) region, to adjust the impedance of the target 17 as viewed from the sputtering power supply 20 side to minimize the reflected power (reactive power) from the target 17.

The type, pressure, and supply amount of sputtering gas or reactive gas required by each target 17 may be different. Therefore, the vacuum chamber 12 is partitioned by the partition walls 24 to separate the respective targets 17, forming the divided chambers 25. Pipe 27 connects the gas supply device 26 (GAS) and divided chamber 25, and a sputtering gas (for example, argon) or a reactive gas (for example, oxygen) is supplied at a predetermined flow rate. The flow rate of the sputtering gas or the reactive gas is controlled by a flowmeter 28 (mass flow controller: MFC).

Although not shown, a plurality of targets 17 may be placed in one divided chamber 25. In this case, it is possible to sputter different materials in the same gas atmosphere. Further, when the sputtering rate of the material of the relevant divided chamber 25 is lower than the sputtering rate of the material of the other divided chamber 25, in order to maintain the transfer speed of the long film 11, sputtering can be also performed by using a plurality of targets 17 of the same material in the relevant divided chamber 25.

The sputtered film adheres to the surface of the long film 11 transferring in synchronization with the rotation of the film forming roll 15 at a position facing the target 17. In FIG. 2, there is one film forming roll 15, but two or more film forming rolls 15 may be provided (not shown).

As the long film 11, generally, a transparent film made of homopolymer or copolymer of polyethylene terephthalate, polybutylene terephthalate, polyamide, polyvinyl chloride, polycarbonate, polystyrene, polypropylene, polyethylene, and the like is used. The long film 11 may be a single layer film or a laminated film with a polarizing film or the like having an optical function. The laminated film is not particularly limited, but may be, for example, a polarizing film including a polarizing layer and at least one protective layer, or a laminated body including a retardation film in the relevant polarizing film. The thickness of the long film 11 is not limited, but is usually about 6 μm to 250 μm.

In the sputtering apparatus 10, a sputtering voltage is applied between the film forming roll 15 and the target 17 with the film forming roll 15 at the anode potential and the target 17 at the cathode potential in a sputtering gas, such as argon. As a result, plasma of sputtering gas is generated between the long film 11 and the target 17. Sputtering gas ions in the plasma collide with the target 17 and knock out constituent materials of the target 17. The constituent material knocked out of the target 17 is deposited on the long film 11 to become a sputtered film.

In the sputtering apparatus 10, the long film 11 before film formation is continuously withdrawn from the supply roll 13 and wound around the film forming roll 15 slightly shorter than one turn, and the film forming roll 15 is rotated to feed the long film 11 in synchronization with the film forming roll 15. The storage roll 16 rewinds the long film 11.

In the sputtering apparatus 10, there are five targets 17, and thus the first layer, the second layer, the third layer, the fourth layer, and the fifth layer are sequentially formed on the long film 11 from the side closer to the supply roll 13. Since the film formation positions of the respective layers are different, there is a time interval between the film formation of each layer. The time interval of film formation of adjacent layers is about ⅕ of the time that the film forming roll 15 makes one rotation, but the time intervals of respective layers may not always be the same. For example, the time interval between the first layer and the second layer and the time interval between the second layer and the third layer may be different.

The sputtering apparatus 10 includes a spectral reflectometer 29 for measuring the spectral reflectance of the multilayer film formed on the long film 11. In the case of FIG. 2, one spectral reflectometer 29 is enough. However, in case there are two or more film forming rolls 15, a spectral reflectometer 29 may be placed on the downstream side of each film forming roll 15, though not shown. In this case, there are two or more spectral reflectometers 29.

The multilayer film produced by the sputtering apparatus 10 has five layers. From the spectral reflectance of the multilayer film measured by the spectral reflectometer 29, for example, the actual measurement value of the hue of the reflected light can be obtained by an analyzer 30. Reflected light from the multilayer film also includes reflected light from the long film 11 (substrate). In the analyzer 30, the estimated thickness value of each layer of the actually formed multilayer film is obtained by the film thickness estimation method described above. The estimated thickness value of each layer thus obtained is transferred from the analyzer 30 to a control device 31.

The flow rate of the reactive gas is controlled for each target using a flowmeter 28 (MFC). The plasma emission intensity is measured by a plasma emission intensity measuring device 32 for each target 17.

The cathode voltage is controlled for each target 17 by a cathode voltmeter 33. By changing the set point of the plasma emission intensity or the cathode voltage, one or more of the flow rate of the sputtering gas, the flow rate of the reactive gas, and the sputtering power are changed, and thereby the thickness of each layer is adjusted.

The control device 31 stores a relation between the amount of adjustment in the film formation parameters (for example, one or more of the flow rate of the sputtering gas, the flow rate of the reactive gas, and the sputtering power) of the first layer to the fifth layer experimentally obtained for the sputtering apparatus 10 and the amount of adjustments in the thicknesses of the first layer to the fifth layer. The film formation parameters of the first layer to the fifth layer are successively adjusted by the control device 31 with a time interval so that the thickness of each layer approaches the target thickness value. Examples of the film formation parameters to be adjusted include plasma emission intensity and cathode voltage.

The plasma emission intensity is used as an input signal of a plasma emission monitoring (PEM) control system, and one or more of the flow rate of the sputtering gas, the flow rate of the reactive gas, and the sputtering power are feedback-controlled by the plasma emission monitoring (PEM) control system. The cathode voltage is controlled by the impedance control system, and one or more of the flow rate of the sputtering gas, the flow rate of the reactive gas, and the sputtering power are feedback-controlled by the impedance control system.

For example, assuming that the time interval of film formation between the first layer and the second layer is 30 seconds, the film formation parameters of the second layer are adjusted 30 seconds after the adjustment of the film formation parameters of the first layer. Assuming that the time interval of film formation between the second layer and the third layer is 35 seconds, the film formation parameters of the third layer are adjusted 35 seconds after the adjustment of the film formation parameters of the second layer. Assuming that the time interval of film formation between the third layer and the fourth layer is 28 seconds, the film formation parameters of the fourth layer are adjusted 28 seconds after the adjustment of the film formation parameters of the third layer. Assuming that the time interval of film formation between the fourth layer and the fifth layer is 33 seconds, the film formation parameters of the fifth layer are adjusted 33 seconds after adjustment of the film formation parameters of the fourth layer.

When the film formation parameters are sequentially adjusted according to the time interval of film formation of each layer in this manner, a multilayer film in which film formation parameters of all layers are adjusted from one position in the longitudinal direction of the long film is obtained. Therefore, for example, in a case where the film formation parameters of the first layer and the second layer must be adjusted, a formation of such an unusable multilayer film as to have only the film formation parameters of the first layer are adjusted while the film formation parameters of the second layer remain unchanged, is prevented. Therefore, waste of neither the substrate, the film forming material nor time occurs.

When forming a multilayer film on the long film 11, it is empirically known how long the fluctuation in the thickness of each layer is in the allowable range of the multilayer film in the longitudinal direction. A predetermined interval in the longitudinal direction is determined based on the length in the longitudinal direction in which the fluctuation in the thickness of each layer of the long film 11 is in the allowable range and the actually measured optical value is measured at each predetermined interval in the longitudinal direction. By doing so, it is possible to prevent fluctuation in the thickness of each layer from exceeding an allowable range without noticing.

When the fluctuation of the thickness of each layer is expected also in the width direction due to the wide widths of the long film 11 and the multilayer film, the actually measured optical values are measured at a plurality of positions in the width direction, the most probable estimated thickness values of each layer are obtained at a plurality of positions in the width direction, and the film formation parameters are adjusted in a divided manner at a plurality of positions in the width direction. By doing so, it is possible to bring the thickness of each layer close to the target thickness value also in the width direction of the multilayer film.

### INDUSTRIAL APPLICABILITY

There is no limitation on the usage of the film formation method for a multilayer film of the present invention, but it is particularly preferably used for forming a multilayer film on a long film.

### DESCRIPTION OF REFERENCE NUMERALS

1: First layer
2: Second layer
3: Third layer
4: Fourth layer
5: Fifth layer
6: Multilayer film
7: Substrate
10: Sputtering apparatus
11: Long film
12: Vacuum chamber
13: Supply roll
14: Guide roll
15: Film forming roll
16: Storage roll
17: Target
18: Cathode
20: Sputtering power supply
24: Partition wall
25: Divided chamber
26: Gas supply device
27: Pipe
28: Flowmeter
29: Spectral reflectometer
30: Analyzer
31: Control device
32: Plasma emission intensity measuring device
33: Cathode voltmeter

1. A film formation method for a multilayer film in which each layer constituting the multilayer film is laminated one by one with a time interval, the film formation method comprising the steps of:
setting a target value (target thickness value) of a thickness of the each layer;
obtaining an estimated thickness (estimated thickness value) of the each layer of the multilayer film formed;
obtaining a film formation parameter change amount of the each layer for minimizing a difference between the target thickness value and the estimated thickness value of the each layer; and
sequentially changing film formation parameters of the each layer used for actual film formation by the film formation parameter change amount of the each layer with the time interval.

2. The film formation method for a multilayer film according to claim 1, wherein a spectral reflectance of the multilayer film is used for obtaining an estimated thickness value of the multilayer film.

3. The film formation method for a multilayer film according to claim 1, wherein a hue of reflected light of the multilayer film is used for obtaining an estimated thickness value of the multilayer.

4. The filth formation method for a multilayer film according to claim 1, wherein each layer constituting the multilayer film is formed by a sputtering apparatus.

5. The film formation method for a multilayer film according to claim 1, wherein the film formation parameters are one or more of a flow rate of a sputtering gas, a flow rate of a reactive gas, and a sputtering power.

6. The film formation method for a multilayer film according to claim 5, wherein one or more of the flow rate of the sputtering gas, the flow rate of the reactive gas, and the sputtering power are feedback-controlled by a plasma emission monitoring (PEM) control system or an impedance control system.

7. The film formation method for a multilayer film according to claim 1, wherein the multilayer film is formed on a surface of a long substrate film.

8. The film formation method for a multilayer film according to claim 7, wherein the actually measured optical value is measured at a predetermined interval in a longitudinal direction of the long substrate film on which the multilayer film is formed.

9. The film formation method for a multilayer film according to claim 1, wherein the multilayer film is an optical multilayer film.
